(19) United States
(12) Patent Application Publication
(10) Pub. No.: US 2026/0056818 A1
(43) Pub. Date: Feb. 26, 2026

(54) MACHINE LEARNING-BASED RESIDENTIAL ENERGY CONSUMPTION ESTIMATION

(71) Applicant: CoreLogic Solutions, LLC, Irvine, CA (US)

(72) Inventors: Shahab Karimi, Carlsbad, CA (US); Fabien Pierre Emile Huard, Carlsbad, CA (US)

(21) Appl. No.: 19/305,595

(22) Filed: Aug. 20, 2025

Related U.S. Application Data
(60) Provisional application No. 63/686,446, filed on Aug. 23, 2024.

(51) Int. Cl. G06F 11/07; G06Q 50/16

(52) U.S. Cl. CPC G06F 11/076; G06F 11/0736; G06Q 50/16

(57) ABSTRACT

Systems and methods for providing estimations of energy consumptions for any given property. Specifically, an energy consumption estimation system may access property energy data (“property data”) relating to existing properties, along with the associated property information or variables (e.g., region, climate, property type, year built). To integrate available property information into the generation of estimation models, the energy consumption estimation system may organize the properties into groups based on a combination of variables. In some cases, the energy consumption estimation system may generate a plurality of groups such that each combination of variables of property information is covered. Accordingly, for each group of properties, the energy consumption estimation system may generate a linear regression model. Each linear regression model may describe a relationship between total energy consumption vs. area for all the properties grouped together by the variables.

### CROSS-REFERENCE TO RELATED APPLICATIONS

The present application claims priority from U.S. Provisional No. 63/686,446, filed on Aug. 23, 2024, entitled MACHINE LEARNING-BASED RESIDENTIAL ENERGY CONSUMPTION ESTIMATION, which is hereby incorporated by reference herein in its entirety.

### BACKGROUND

Estimation of the total gross annual energy consumption of a property (e.g., residential) may depend on a variety of factors. For example, a property's region, climate, property type, year built, and area may each contribute to the total consumption estimate. Although not absolute, total energy consumption of the property may generally follow a linear model with respect to the property's area (e.g., square footage).

### SUMMARY

The systems, methods, and devices of this disclosure each have several innovative aspects, no single one of which is solely responsible for all of the desirable attributes disclosed herein. Details of one or more implementations of the subject matter described in this specification are set forth in the accompanying drawings and descriptions below.

In some aspects, the techniques described herein relate to a system, comprising: a computer-readable storage medium storing program instructions. The system further comprises one or more processors configured to execute the program instructions to cause the system to: access property data, the property data comprising a plurality of properties and associated energy information with each of the plurality of properties, wherein each property of the plurality of properties is identified with a set of variables including a region, a climate, a property type, and a construction year; generate a group comprising a subset of the plurality of properties identified by the set of variables; generate a linear regression model corresponding to the group, the linear regression model representing a correlation between estimated energy consumption and an area of each of the subset of the plurality of properties; determine an error corresponding to the generated linear regression model; and sort the linear regression model into a first data store when the error is under a first error threshold and into a second data store when the error is under a second error threshold.

In some aspects, the techniques described herein relate to a system, wherein the energy information comprises at least one of a statistic, survey, poll, investigation, energy usage, or a sampling.

In some aspects, the techniques described herein relate to a system, wherein the error is a mean absolute percentage error.

In some aspects, the techniques described herein relate to a system, wherein the one or more processors further cause the system to: discard the linear regression model when the error is greater than the first error threshold and the second error threshold.

In some aspects, the techniques described herein relate to a system, wherein the one or more processors are configured to execute the program instructions to further cause the system to: generate a plurality of linear regression models corresponding to the group; determine, for each linear regression model of the plurality of linear regression models, an error corresponding to the generated linear regression model; and sort each linear regression model of the plurality of linear regression models into the first data store when the error is under a first error threshold and into the second data store when the error is under a second error threshold.

In some aspects, the techniques described herein relate to a system, wherein the one or more processors are configured to execute the program instructions to further cause the system to: generate an estimate of a property of the plurality of properties based on the linear regression model.

In some aspects, the techniques described herein relate to a system, wherein the one or more processors are configured to execute the program instructions to further cause the system to: generate a plurality of estimates of a property of the plurality of properties based on the linear regression model; determine an average energy consumption estimate based on the plurality of estimates of the property; and transmit the average energy consumption estimate to a computing device.

In some aspects, the techniques described herein relate to a system, comprising: a computer-readable storage medium storing program instructions; and one or more processors configured to execute the program instructions to cause the system to: receive a request for an energy consumption estimate of a property, the property associated with a set of variables; generate a first estimate of the property based on a first linear regression model; determine that the first linear regression model is not associated with the set of variables; generate a second estimate of the property based on a second linear regression model in response to the determination that the first linear regression model is not associated with the set of variables; determine an average energy consumption estimate based on the second estimate of the property; and transmit the average energy consumption estimate to a computing device.

In some aspects, the techniques described herein relate to a system, wherein the set of variables includes at least one of a region, a climate, a property type, or a construction year.

In some aspects, the techniques described herein relate to a system, wherein the first linear regression model has an error under a first error threshold.

In some aspects, the techniques described herein relate to a system, wherein the second linear regression model has an error under a second error threshold, and wherein the second error threshold is greater than the first error threshold.

In some aspects, the techniques described herein relate to a system, wherein the first linear regression model was generated based on a second set of variables different from the set of variables.

In some aspects, the techniques described herein relate to a system, wherein the property is identified in the request by a geographical location.

In some aspects, the techniques described herein relate to a method, comprising: accessing property data, the property data comprising a plurality of properties and associated energy information with each of the plurality of properties, wherein each property of the plurality of properties is identified with a set of variables including a region, a climate, a property type, and a construction year; generating a group comprising a subset of the plurality of properties identified by the set of variables; generating a linear regression model corresponding to the group, the linear regression model representing a correlation between estimated energy consumption and an area of each of the subset of the plurality of properties; determining an error corresponding to the generated linear regression model; and sorting the linear regression model into a first data store when the error is under a first error threshold and into a second data store when the error is under a second error threshold.

In some aspects, the techniques described herein relate to a method, comprising wherein the energy information comprises at least one of a statistic, survey, poll, investigation, energy usage, or a sampling.

In some aspects, the techniques described herein relate to a method, comprising wherein the error is a mean absolute percentage error.

In some aspects, the techniques described herein relate to a method, comprising further comprising: discarding the linear regression model when the error is greater than the first error threshold and the second error threshold.

In some aspects, the techniques described herein relate to a method, comprising further comprising: generating a plurality of linear regression models corresponding to the group; determining, for each linear regression model of the plurality of linear regression models, an error corresponding to the generated linear regression model; and sorting each linear regression model of the plurality of linear regression models into the first data store when the error is under a first error threshold and into the second data store when the error is under a second error threshold.

In some aspects, the techniques described herein relate to a method, comprising further comprising: generating an estimate of a property of the plurality of properties based on the linear regression model.

In some aspects, the techniques described herein relate to a method, comprising further comprising: generating a plurality of estimates of a property of the plurality of properties based on the linear regression model; determining an average energy consumption estimate based on the plurality of estimates of the property; and transmitting the average energy consumption estimate to a computing device.

### BRIEF DESCRIPTION OF THE DRAWINGS

Various features will now be described with reference to the following drawings. Throughout the drawings, reference numbers may be re-used to indicate correspondence between referenced elements. The drawings are provided to illustrate examples described herein and are not intended to limit the scope of the disclosure.

FIG. 1 is a schematic block diagram of an example network environment in which an energy consumption estimation system may operate, according to various aspects of the present disclosure.

FIG. 2 is an example data flow process in which the energy consumption estimation system may operate to generate linear regression models based on property energy data, according to various aspects of the present disclosure.

FIG. 3 is an example data flow process in which the energy consumption estimation system may operate to generate an estimation based on generated linear regression models, according to various aspects of the present disclosure.

FIG. 4 is an example linear regression model generated by the energy consumption estimation system, according to various aspects of the present disclosure.

FIG. 5 is a block diagram illustrating components of an example computing system that can be used to implement the various systems and methods described herein.

FIG. 6 is a flow diagram showing an example routine for generating a linear regression model corresponding to energy consumption estimation of properties, according to various aspects of the present disclosure.

FIG. 7 is a flow diagram showing an example routine for providing energy consumption estimations for properties based on generated linear regression models.

### DETAILED DESCRIPTION

Generally described, aspects of the present disclosure relate to efficient mechanisms for providing energy consumption estimations for properties based on generated linear regression models.

Energy consumption as used herein may refer to a total amount of energy utilized by a property over the course of any time interval (e.g., a year). Energy consumption may include the use of electricity (e.g., grid), natural gas, fuel, oil, propane, and even wood. Estimation of the total energy consumption of any given property may be a useful metric to owners, prospective buyers, brokers, agents, utility companies, and even governmental or environmental agencies.

Energy consumption may generally follow a linear relationship between the total living area and the overall energy consumption. However, energy consumption for a property may also depend on a variety of factors. As noted herein, total energy consumption may vary widely based on a property's region, climate, property type, year built, area, among others. Because of the variance of consumption across a multitude of properties, models may be used to estimate energy consumption. However, due to a lack of available real world information relating to energy consumption by properties (e.g., actual energy consumption tracked by utilities companies, which may be kept confidential by the utilities companies), existing estimation models lack accuracy and/or the capability to estimate consumption for all types of properties. In addition, methodologies utilized by existing models typically take a “top down” approach, which may not optimally capture the intrinsic linear relationship between the total living area of a property and the overall energy consumption. For example, top down models typically rely on pre-existing knowledge and rules to guide decision-making. Because energy consumption across properties is highly variable and may not follow pre-defined rules, this approach may not be a good fit. “Bottom up” models, such as neural networks, may also not accurately capture this relationship as these models focus on discovering patterns and rules based on data. Although these models may take into account the vast amount of property energy data, these models may ignore or de-emphasize the intrinsic linear relationship between area and energy consumption.

As will be appreciated by one of skill in the art in light of the present disclosure, the embodiments disclosed herein improve the ability of computing systems, such as the energy consumption estimation system, to provide estimations of energy consumptions for any given property. Specifically, the energy consumption estimation system may access property energy data (“property data”) relating to existing properties, along with the associated property information or variables (e.g., region, climate, property type, year built). To integrate available property information into the generation of estimation models, the energy consumption estimation system may organize the properties into groups based on a combination of variables. In some cases, the energy consumption estimation system may generate a plurality of groups such that each combination of variables of property information is covered. This may allow the energy consumption estimation system to generate machine learning models (e.g., linear regression models) for every property variation of the property energy data (e.g., across all regions, climates, property types, years built). Machine learning models that utilize a linear regression approach may assume a linear relationship between a target variable and features. Because of the intrinsic relationship between property area and energy consumption (e.g., larger property means higher energy consumption), linear regression models may predict energy consumption accurately according to this relationship while balancing variable features. Accordingly, for each group of properties, the energy consumption estimation system may generate a linear regression model. Each linear regression model may describe a relationship between total energy consumption vs. area for all the properties grouped together by the variables.

Because of the wide variance of the estimated energy consumptions as a function of the property area, the generated linear regression models may be subject to error. In addition, certain groups may contain fewer properties than other groups (e.g., properties in Alaska may be sparser than the properties in California), leading to certain linear regression models generated from many data points and other linear regression models generated from few data points. In some embodiments, the energy estimation system determines an error for each generated linear regression model. Accordingly, the energy consumption estimation system may sort the generated linear regression models into multiple categories based on the amount of error.

As noted herein, estimation of the total gross annual energy consumption of a property (e.g., residential) may depend on a variety of factors. For example, a property's region, climate, property type, year built, and area may each contribute to the total consumption estimate. Although not absolute, total energy consumption of the property may generally follow a linear model with respect to the property's area (e.g., square footage). As such, in some cases, the generated linear regression models, generated based on the variety of factors, may be used to estimate total energy consumption of a property. To generate an energy consumption estimate, the energy consumption estimation system can receive a request relating to any given property. Generated linear regression models can be used to estimate an energy consumption of the requested property.

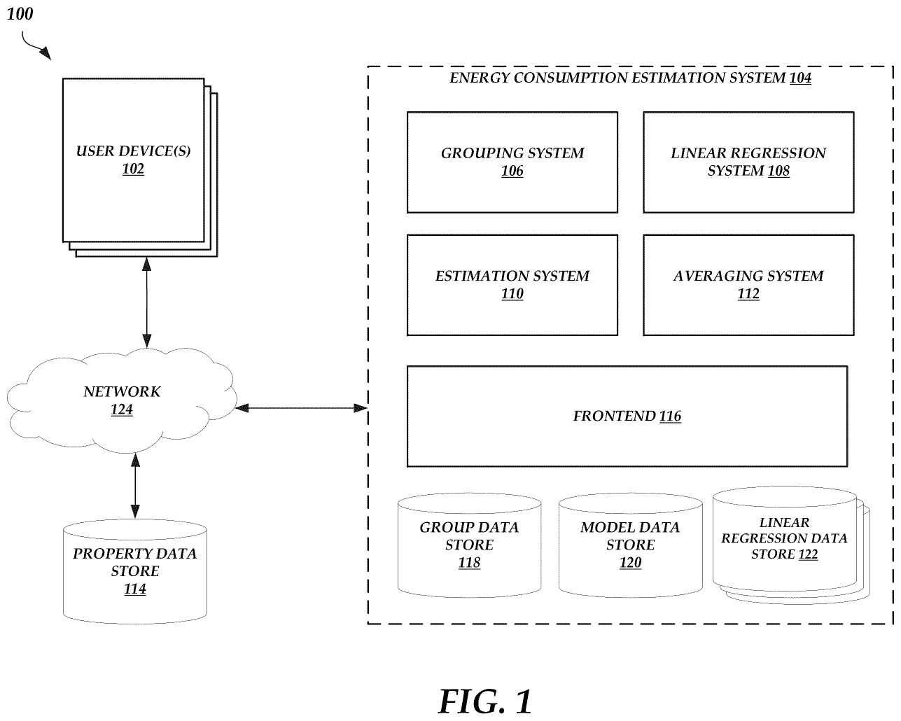

FIG. 1 is a schematic block diagram of an example network environment 100 in which an energy consumption estimation system 104 may operate, according to various aspects of the present disclosure. The energy consumption estimation system 104 may be configured to provide energy consumption estimations for properties (e.g., residential) based on generated linear regression models.

As shown in FIG. 1, the network environment 100 includes user device(s) 102 (hereinafter referred to as “user device 102” for ease of reference), energy consumption estimation system 104, property energy data store 114, and network 124. Energy consumption estimation system 104 includes grouping system 106, linear regression system 108, estimation system 110, averaging system 112, frontend 116, group data store 118, model data store 120, and linear regression data store(s) 122. The components of the energy consumption estimation system 104 within network environment 100 may be communicatively coupled via network 124. In addition, network 124 may connect the user device 102 to the energy consumption estimation system 104 and various components of the energy consumption estimation system 104. The network environment 100 and components of network environment 100 can include various hardware components and software components and can provide functionality as described further herein. In addition, components of the network environment 100 and the energy consumption estimation system 104 can include more or less components.

In various aspects, communication among the various components of the example network environment 100 and the energy consumption estimation system 104 may be accomplished via any suitable device, systems, methods, and/or the like. For example, the energy consumption estimation system 104 may communicate with the user device 102 and any datastores, such as the property energy data store 114, via any combination of the network 124 or any other wired or wireless communication networks, methods (e.g., Bluetooth, WiFi, infrared, cellular, and/or the like). As further described below, the network 124 may comprise, for example, one or more internal or external networks, the Internet, and/or the like.

Network 124 of the network environment 100 can include any appropriate network, including wired network, wireless network, or combination thereof. For example, network 124 may be a personal area network, local area network, wide area network, cable network, satellite network, cellular network, or any other such network or combination thereof. As a further example, the network 124 may be a publicly accessible network of linked networks, possibly operated by various distinct parties, such as the Internet. Protocols and components for communicating via the Internet or any other types of communication networks are known to those skilled in the art of computer communications and thus, need not be described in more detail herein. In various embodiments, the network 124 may be a private or semi-private network, such as a corporate or university intranet. The network 124 may include one or more wireless networks, such as a Global System for Mobile Communications (GSM) network, a Code Division Multiple Access (CDMA) network, a Long-Term Evolution (LTE) network, C-band, mmWave, sub-6 GHz, or any other type of wireless network. The network 124 can use protocols and components for communicating via the Internet or any of the other aforementioned types of networks. For example, the protocols used by the network 124 may include Hypertext Transfer Protocol (HTTP), HTTP Secure (HTTPS), Message Queue Telemetry Transport (MQTT), Constrained Application Protocol (CoAP), and the like. Protocols and components for communicating via the Internet or any of the other aforementioned types of communication networks are well known to those skilled in the art of computer communications and thus, need not be described in more detail herein.

In various implementations, the network 124 can represent a network that may be local to a particular organization, e.g., a private or semi-private network, such as a corporate or university intranet. In some implementations, devices may communicate via the network 124 without traversing an external network, such as the Internet. In some implementations, devices connected via the network 124 may be walled off from accessing the Internet. As an example, the network 124 may not be connected to the Internet. Accordingly, e.g., the user device 102 may communicate with the energy consumption estimation system 104 directly (via wired or wireless communications) or via the network 124, without using the Internet. Thus, even if the network 124 or the Internet is down, the energy consumption estimation system 104 may continue to communicate and function via direct communications (and/or via the network 124).

User device 102 may be used to access various components of the network environment 100 and the energy consumption estimation system 104 over the network 124. User device 102 illustratively correspond to any computing device that provides a means for a user or admin to interact with components of the energy consumption estimation system 104. For example, a user, with user device 102, may access the energy consumption estimation system 104 via the frontend 116 to request information or data (e.g., energy consumption estimates) provided by the energy consumption estimation system 104. In some examples, the frontend 116 may be implemented on user device 102. Of course, other activities may also be performed by a user with a user device 102. User device 102 may include user interfaces or dashboards that connect a user with a machine, system, or device. In various implementations, user device 102 include computer devices with a display and a mechanism for user input (e.g., mouse, keyboard, voice recognition, touch screen, and/or the like). In various implementations, the user device 102 include desktops, tablets, e-readers, servers, wearable device, laptops, smartphones, computers, gaming consoles, and the like. In some implementations, user device 102 can access a cloud provider network via the network 124 to view or manage their data and computing resources, as well as to use websites and/or applications hosted by the cloud provider network. Elements of the cloud provider network may also act as clients to other elements of that network. Thus, user device 102 can generally refer to any device accessing a network-accessible service as a client of that service.

Property energy data store 114 may be configured to store data relating to energy information of properties. Property energy information can include data derived from surveys, polls, investigations, statistics, other sources, and the like. However, the property energy information may not include actual energy usage of individual parcels calculated by utilities companies. The U.S. Energy Information Administration (“EIA”) is an organization that conducts a nationally representative sampling of houses to collect various energy characteristics. The Residential Energy Consumption Survey (“RECS”) is administered by the EIA every several years to collect data from a representative sampling of housing units that may include household demographics, energy use patterns, and housing unit characteristics. In a first part of the RECS, a cross-sectional household survey collects energy-related characteristics and energy usage data. In a second part, energy suppliers for housing units may be surveyed for billing data, which may then be used to estimate energy consumption and expenditure. In some embodiments, property energy data store 114 stores information derived from RECS and other surveys indicative of housing unit energy information. Property energy data store 114 may be updated upon publication of new surveys and the like. In some embodiments, each surveyed property may be associated with additional information relating to the property itself (e.g., region, climate, property type, year built, area). Region, for example, may include general locations and sublocations: Northeast (e.g., New England, Middle Atlantic), Midwest (e.g., East North Central, West North Central), South (e.g., South Atlantic, East South Central, West South Central), West, Mountains, Pacific), and the like. Climate may refer to any long-term weather pattern in an area, such as cold, hot-humid, marine, hot-dry, mixed-humid, subarctic, very cold, mixed dry. In addition, climates can also include tropical, dry, temperate, arid, continental, polar, humid, mixed). Property type may refer to the structure or features of the property or residence, such as single-family detached, single-family attached, apartment, mobile home, etc. Other features may be included such as total number of rooms, stories, building materials, amenities, and the like. Year built may refer to the year in which the property was constructed. Area may refer to a square footage of the property, or any other relevant metric indicating the size of the property. For example, the property energy data store 114 may store information relating to Property X. In this example, Property X is recorded to have utilized 10,000 kWh of energy over the past year. In addition, Property X is located in the Northeast region, cold climate, is a single-family type house, and is about 2,300 square feet.

Energy consumption estimation system 104 may be configured to provide energy consumption estimations for properties (e.g., residential) based on generated linear regression models. In some embodiments, the energy consumption estimation system 104 may access historical or survey data, such as data stored in the property energy data store 114. The energy consumption estimation system 104 may utilize the accessed historical or survey data to generate linear regression models.

Energy consumption estimation system 104 may have access to various databases, models, and other applications that allow the energy consumption estimation system 104 to provide energy estimates for properties. As shown in FIG. 1, the energy consumption estimation system 104 includes various systems, such as the grouping system 106, the linear regression system 108, the estimation system 110, the averaging system 112, and the frontend 116. In addition, energy consumption estimation system 104 has access to various data bases or data stores, such as group data store 118, model data store 120, linear regression data store 122. Energy consumption estimation system 104 may include or have access to additional components not shown in FIG. 1, or may have less components than as shown. Each component of the energy consumption estimation system 104 will be discussed in turn below.

To facilitate interaction between the energy consumption estimation system 104 and a user of the user device 102 via the network 124, the energy consumption estimation system 104 includes the frontend 116. Frontend 116 may include any presentation layer (e.g., experience layer) such as a user-facing interface or platform through which a user of the user device 102 may access and interact with the energy consumption estimation system 104. In some embodiments, a user of the user device 102 submits a request for an energy estimation of a particular property through the frontend 116.

To generate linear regression models for estimating property energy consumption, the energy consumption estimation system 104 may access various systems or components.

Energy consumption estimation system 104 may comprise various systems or modules configured to execute processes directed to generating models for energy estimation. In a first part, the energy consumption estimation system 104 may access energy data from the property energy data store 114. Property energy data may be utilized by the various components of the energy consumption estimation system 104 to generate estimation models.

Grouping system 106 may be configured to generate groups or “slices” based on the accessed information from the property energy data store 114. Each group may comprise properties that are classified by the combination of variables in that group. As noted herein, property energy data may relate to existing properties and may include “variables” (e.g., region, climate, property type, year built). Each property stored in the property energy data store 114 may be identified by the variables. To generate a group, the grouping system 106 may generate a combination of variables and access properties that are classified under that combination. For example, the grouping system 106 may generate a group corresponding to single-family detached homes (property type) in the South (region) with hot-humid climate (climate) which was built after 1990 (year built). To fully capture the information within the property energy data store 114, the grouping system 106 may generate a group for each variation of variable combinations. For example, in some cases, the energy consumption estimation system may generate a plurality of groups such that each combination of variables of property information is covered, e.g., a group to cover every possible combination of region, climate, property type, and year built. In some embodiments, each property in the property energy data store 114 may be categorized into at least one group. Groups may be stored in the group data store 118.

Linear regression system 108 may, for every group, determine a linear regression line or model. The linear regression model may describe the relationship between energy consumption and area for all the properties classified by the group variables. In some embodiments, the linear regression models for each group may be stored in the linear regression data store 122.

Estimation system 110 may be configured to provide an estimated energy consumption for any property. To generate an estimate, the estimation system 110 may access the linear regression data store 122. As noted herein, the linear regression data store 122 may store linear regression models. In some embodiments, the linear regression data store 122 may be organized or divided into multiple data stores to store subsets of linear regression models. Estimation system 110 may utilize at least one generated linear regression model to output an estimate corresponding to a total energy consumption (e.g., annual) for a requested property.

Averaging system 112 may be configured to average the estimations generated by the estimation system 110. As will be described in more detail below, the estimation system 110 may access more than one data store containing linear regression models. As such, the estimation system 110 may, for a given estimate request, may utilize various averaging methods or techniques to average the estimates from the estimation system 110. For example, the averaging system 112 may utilize a mean, median, mode, or any other technique.

Group data store 118 may be configured to store the groups generated by the grouping system 106. As noted above, the grouping system 106 can generate groups or based on the accessed information from the property energy data store 114. In addition, each group may comprise properties that are classified by the combination of variables in that group. Groups may be stored in the group data store 118 and may be organized or identified by the variables.

Model data store 120 may be configured to store models, algorithms, or other processes to be accessed by the energy consumption estimation system 104. Models stored in the model data store 120 may include any engine, service, application, program, process, etc. configured to generate linear regressions. In some embodiments, models may include machine learning (ML) models, artificial intelligence (AI) models, neural networks, and the like.

Linear regression data store 122 may be configured to store the generated linear regression models. In some embodiments, linear regression data store 122 comprises multiple data stores. As noted herein, the grouping system 106 may generate multiple groups based on the various combinations of variables. As such, the linear regression system 108 may generate a plurality of linear regression models corresponding to each group. In some cases, the linear regression data store 122 may store a subset of the generated linear regression models based on error. In an example, the energy consumption estimation system 104 may sort all linear regression models with an error (e.g., mean absolute percentage error) less than a threshold percentage (e.g., 35%, 40%, etc.) into first linear regression data store. In addition, the energy consumption estimation system 104 may sort all remaining linear regression models with an error less than 45% into a second linear regression data store. All linear regression models that do not meet these error threshold may be discarded or stored in additional data stores.

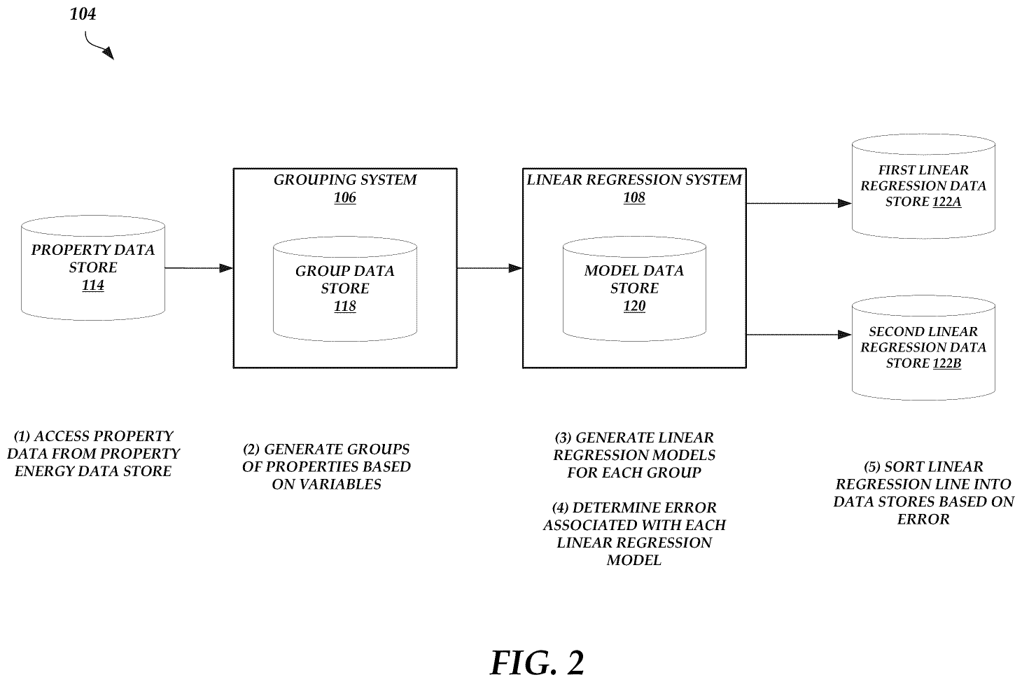

FIG. 2 is an example data flow process in which the energy consumption estimation system 104 may operate to generate linear regression models based on property energy data.

At (1), the energy consumption estimation system 104 accesses property energy data from the property energy data store 114. Property energy data store 114 may store information relating to energy information of properties. As noted herein, property energy information may be derived from various surveys, polls, and other sources that capture energy data associated with existing properties. In some examples, the energy consumption estimation system 104 accesses the property energy data store 114, which may be located remotely and accessible via the network 124.

At (2), the energy consumption estimation system 104 utilizes the information stored in property energy data store 114 to generate property groups. As noted herein, properties stored in the property energy data store 114 can be associated with variables (e.g., region, climate, property type, year built, area). These variables indicate additional information associated with each property, and may be utilized by the energy consumption estimation system 104 to improve the accuracy of energy estimation. To integrate property information into generated linear regression models, the energy consumption estimation system 104 may first, via the grouping system 106, generate groups. Each group may comprise properties that are classified by the combination of variables in that group. For example, the grouping system 106 may generate a group comprising properties that are identified by the following variables: Pacific (region), marine (climate), apartment in building with 2-4 units (property type), built within 1990-1999 (year built). The grouping system 106 may access, from the property energy data store 114, all properties that fit this description for classification as a group. In some embodiments, the grouping system 106 may determine a group for every combination of variables. Each property in the property energy data store 114 may be categorized into at least one group. Groups may be stored in the group data store 118.

At (3), upon generation of the groups by the grouping system 106, the linear regression system 108 generates a linear regression line or model for each group. The linear regression model generated by the linear regression system 108 may describe the relationship between energy consumption and the property area. As shown in FIG. 2, the linear regression system 108 may access model data store 120. To generate a linear regression model for a group, the linear regression system 108 may input the group into the model of model data store 120 and any corresponding prompt or instruction to generate the linear regression model. In the example above, the linear regression system 108 may receive a property group corresponding to all properties from the property energy data store 114 that fit the description of: Pacific (region), marine (climate), apartment in building with 2-4 units (property type), built within 1990-1999 (year built). The linear regression system 108 may input this information into the model configured to output a linear regression model that describes total energy consumption v. area. In some embodiments, the linear regression system 108 may generate linear regression models for each property group for storage in the linear regression data store 122. As such, the linear regression system 108 may generate a linear regression model for each combination of variables such that each property of the property energy data store 114 is described by at least one linear regression model.

Because of the wide variance of the estimated energy consumptions as a function of the property area, the generated linear regression models may be subject to error. In addition, certain groups may contain fewer properties than other groups (e.g., properties in Alaska may be sparser than the properties in California), leading to certain linear regression models generated from many data points and other linear regression models generated from few data points. In some embodiments, groups are discarded if there are too few properties within that group (e.g., less than 10 properties, less than 25 properties, less than 50 properties, etc.). Accordingly, at (4), the linear regression system 108 determines an error of each linear regression model. In some embodiments, the linear regression system 108 determines the error of the linear regression models using various error calculation methods or processes. In one instance, the linear regression system 108 calculates the mean absolute percentage error (“MAPE”) of each linear regression model. The MAPE calculated for each linear regression model may indicate the average magnitude of error produced by the generated linear regression.

Accordingly, energy consumption estimation system 104 may sort the generated linear regression models into multiple categories based on the amount of error. At (5), the energy consumption estimation system 104 sorts each linear regression model into a data store. As shown in FIG. 2, the energy consumption estimation system 104 may sort each linear regression model into either first linear regression data store 122A or second linear regression data store 122B. In some embodiments, the energy consumption estimation system 104 may sort the linear regression models into additional data stores. Additionally, at (5), the energy consumption estimation system 104 may sort each linear regression model based on the determined MAPE. In some embodiments, the energy consumption estimation system 104 may utilize a threshold percentage or value to determine which data store to store each linear regression model. For example, the energy consumption estimation system 104 may sort all linear regression models with a MAPE less than 35% into first linear regression data store 122A. In addition, the energy consumption estimation system 104 may sort all remaining linear regression models with a MAPE less than 45% into the second linear regression data store 122B. All linear regression models that do not meet these error threshold may be discarded. The energy consumption estimation system 104 may utilize various threshold percentages for sorting the linear regression models, and may include more or less data stores.

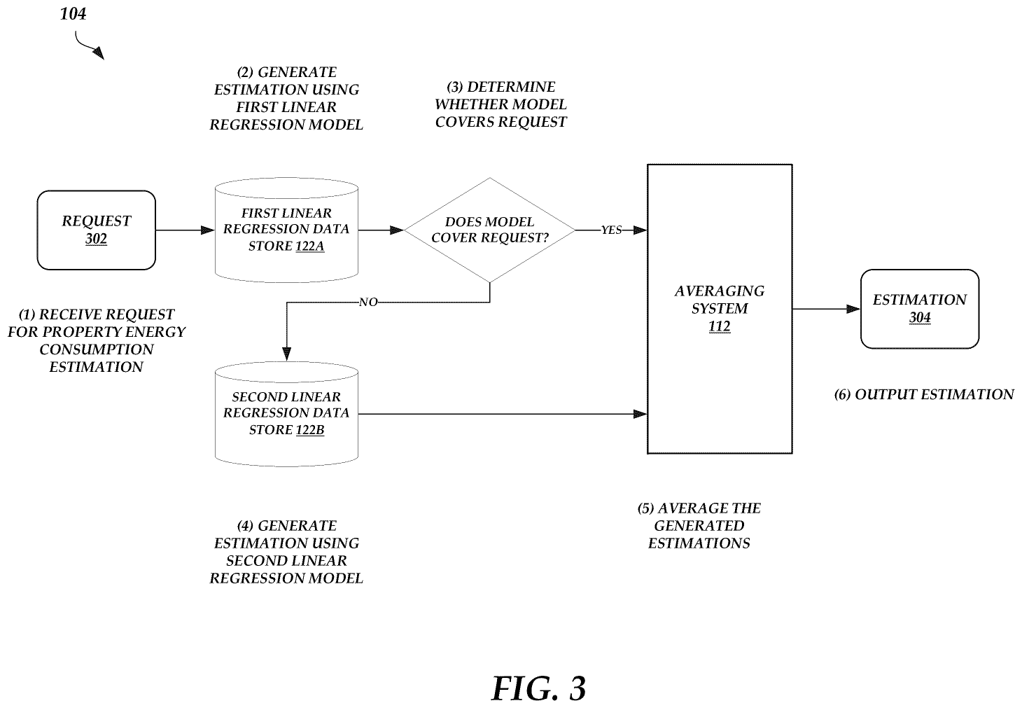

FIG. 3 an example data flow process in which the energy consumption estimation system 104 may operate to generate an estimation 304 based on generated linear regression models, according to various aspects of the present disclosure.

At (1), the energy consumption estimation system 104, via the estimation system 110, receives a request 302. Request 302 may be a request for an energy consumption estimation of a property. The request 302 may indicate a request for an average energy consumption estimation of a property over a specified time period, such as a year (e.g., total gross annual energy consumption). In some embodiments, a user of the user device 102 may input a request 302 to the energy consumption estimation system 104 via the frontend 116. The request 302 may identify a specific property that is tied to a geographical location (e.g., identified by an address). In some cases, the request 302 may identify a hypothetical property that is not specifically tied to a real world geographical location, but may be identified in the request 302 by features or other identifiers. In some examples, the request 302 identifies the area (e.g., square footage) of the requested property.

At (2), the estimation system 110 generates an estimation 304 corresponding to the requested property using a first linear regression model. As described above with respect to FIG. 2, the first linear regression data store 122A may store a subset of generated linear regression models, such as those with a MAPE of less than 35%. To estimate the energy consumption of the requested property, the estimation system 110 may utilize the linear regression models in the first linear regression data store 122A to output an estimation 304. In some embodiments, the estimation system 110 may utilize each linear regression model of the first linear regression data store 122A to generate multiple estimations for a requested property.

At (3), the estimation system 110 determines whether the linear regression model(s) covers the requested property. As noted herein, each linear regression model generated by the linear regression system 108 may be based on a group that defines a certain classification of properties (of property energy data store 114). Although property energy data store 114 may contain multiple properties that span various regions, climates, property types, etc., the available property data may not be wholly comprehensive. As such, there may be certain scenarios in which a requested property is not explicitly covered by the generated linear regression models. For example, request 302 may identify a multi-family house in a remote area of Alaska. Property energy data store 114 may not contain property information with these variables, and as such, the linear regression system 108 would not have taken this type of property into account when generating a linear regression model. In another instance, linear regression system 108 may have generated a linear regression model integrating a similar property (e.g., very cold climate, multi-family home), but may have discarded the linear regression model due to a high presence of error. As such, at (3), the estimation system 110 may determine whether the requested property in the request 302 is covered by any one of the linear regression models stored in 122A. In the case when the estimation system 110 determines that the requested property is covered by at least one of the linear regression models, the estimation system 110 skips (4) and proceeds to the averaging system 112.

In the case when the estimation system 110 determines that the requested property is not covered by at least one of the linear regression models of the first linear regression data store 122A, the estimation system 110, at (4), generates an estimation 304 corresponding to the requested property using a second linear regression model. As described above with respect to FIG. 2, the second linear regression data store 122B may store a subset of generated linear regression models, such as those with a MAPE of less than 45%. To estimate the energy consumption of the requested property, the estimation system 110 may utilize the linear regression models in the second linear regression data store 122B to output an estimation 304. In some embodiments, the estimation system 110 may utilize each linear regression model of the second linear regression data store 122B to generate multiple estimations for a requested property. In some embodiments, at (4), the estimation system 110 discards the previously-estimations generated with the first linear regression data store 122A.

At (5), the averaging system 112 averages the generated estimations. As noted above, the estimation system 110 may generate multiple estimations using the linear regression models in either first linear regression data store 122A or second linear regression data store 122B. Averaging system 112 may average the estimations into a single estimation 304.

At (6), the energy consumption estimation system 104 may output the estimation 304. Estimation 304 may be output to a user of the user device 102, such as via the frontend 116. In some embodiments, the estimation 304 may be transmitted to another process, system, or device for further processing.

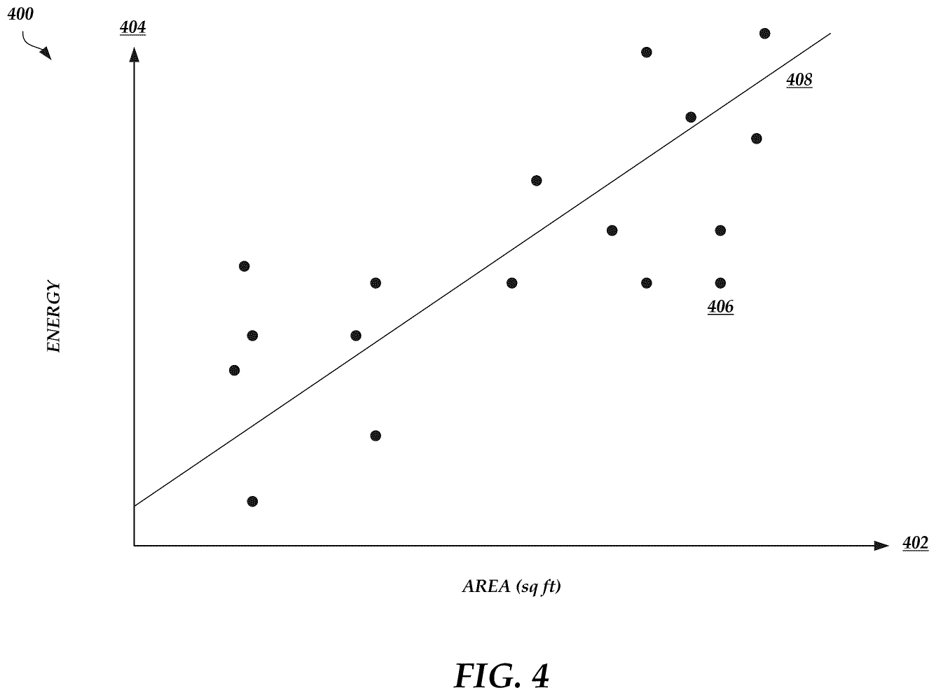

FIG. 4 is an example linear regression model 400 generated by the energy consumption estimation system 104. Linear regression model 400 may correspond to any group and may be stored in the linear regression data store 122.

As shown in FIG. 4, linear regression model 400 is represented as a graph. X-axis 402 represents the area (e.g., square feet) and the y-axis 404 is the energy consumption. Energy consumption may be any appropriate unit or metric, such as kilowatt-hour (kWh), British thermal unit (BTU), joules (J), or the like.

FIG. 4 may correspond to a linear regression model 400 corresponding to a given property group. As such, each data point in the linear regression model 400 corresponds to a property (of property energy data store 114) within the group that is classified by the group's variables (e.g., region, climate, property type, year built). For example, data point 406 corresponds to a property that is classified within the generated group and is associated with each of the specified variables. To generate the linear regression model 400, the linear regression system 108 may plot each property of the group on a graph that represents the estimated energy consumption as a function of the property area. As shown in linear regression model 400, there exist 17 properties within the group.

To generate a linear regression model for a group, the linear regression system 108 may input the group into the model and any corresponding prompt or instruction to generate the linear regression model. This is shown in FIG. 4 as linear regression line 408. The linear regression line 408 may describe the relationship between energy consumption and area for all the properties classified by this particular group.

In some embodiments, the energy consumption estimation system 104 stores the linear regression model 400 in the linear regression data store 122. Linear regression model 400 may be accessed by a user of the user device 102, or may be output or transmitted for further processing.

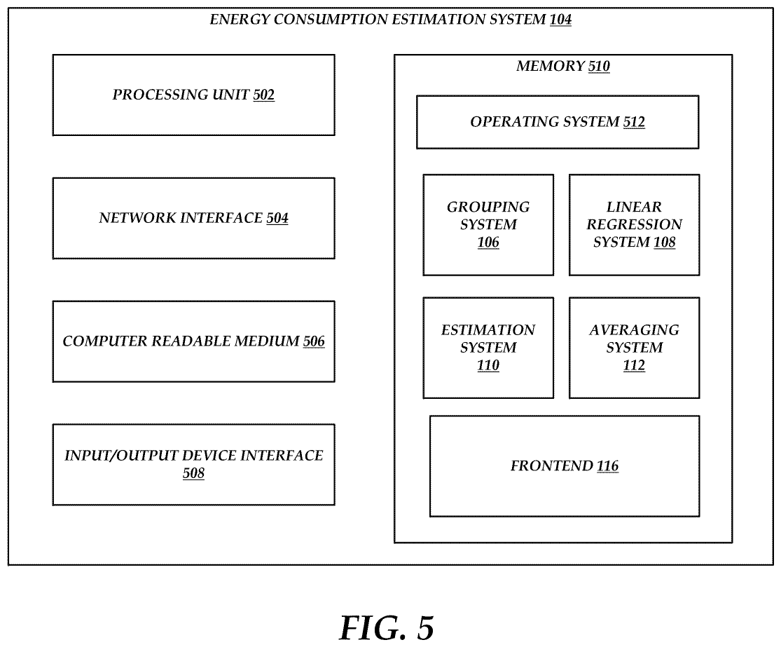

FIG. 5 is a block diagram illustrating components of an example computing system that can be used to implement the various systems and methods described herein.

The general architecture of the system depicted in FIG. 5 includes an arrangement of computer hardware and software that may be used to implement aspects of the present disclosure. The hardware may be implemented on physical electronic devices, as discussed in greater detail below. The system may include many more (or fewer) elements than those shown in FIG. 5. It is not necessary, however, that all of these generally conventional elements be shown in order to provide an enabling disclosure. Additionally, the general architecture illustrated in FIG. 5 may be used to implement one or more of the other components illustrated in the figures. As illustrated, the system includes a processing unit 502, a network interface 504, a computer-readable medium drive 506, and an input/output device interface 508, and memory 510, all of which may communicate with one another by way of a communication bus.

The network interface 504 may provide connectivity to one or more networks or computing systems. The processing unit 502 may thus receive information and instructions from other computing systems or services via the network. The processing unit 502 may also communicate to and from memory 510 and further provide output information for an optional display (not shown) via the input/output device interface 508. The input/output device interface 508 may also accept input from an optional input device (not shown).

The memory 510 may contain computer program instructions (grouped as units in some embodiments) that the processing unit 502 executes in order to implement one or more aspects of the present disclosure, along with data used to facilitate or support such execution. While shown in FIG. 5 as a single set of memory 510, memory 510 may in practice be divided into tiers, such as prim. memory and secondary memory, which tiers may include (but are not limited to) random access memory (RAM), 3D XPOINT memory, flash memory, magnetic storage, and the like. For example, primary memory may be assumed for the purposes of. scription to represent a main working memory of the system, with a higher speed but lower total capacity than a secondary memory, tertiary memory, etc.

The memory 510 may store an operating system 512 that provides computer program instructions for use by the processing unit 502 in the general administration and operation of the energy consumption estimation system 104. The memory 510 may further include computer program instructions and other information for implementing aspects of the present disclosure. For example, in one embodiment, the memory 510 includes the grouping system 106, the linear regression system 108, the estimation system 110, averaging system 112, and the frontend 116. Each of these components may represent code executable to perform the processes described herein.

The system of FIG. 5 is one illustrative configuration of such a device, of which others are possible. For example, while shown as a single device, a system may in some embodiments be implemented as a logical device hosted by multiple physical host devices. In other embodiments, the system may be implemented as one or more virtual devices executing on a physical computing device. While described in FIG. 5 as an energy consumption estimation system 104, similar components may be utilized in some embodiments to implement other devices shown herein.

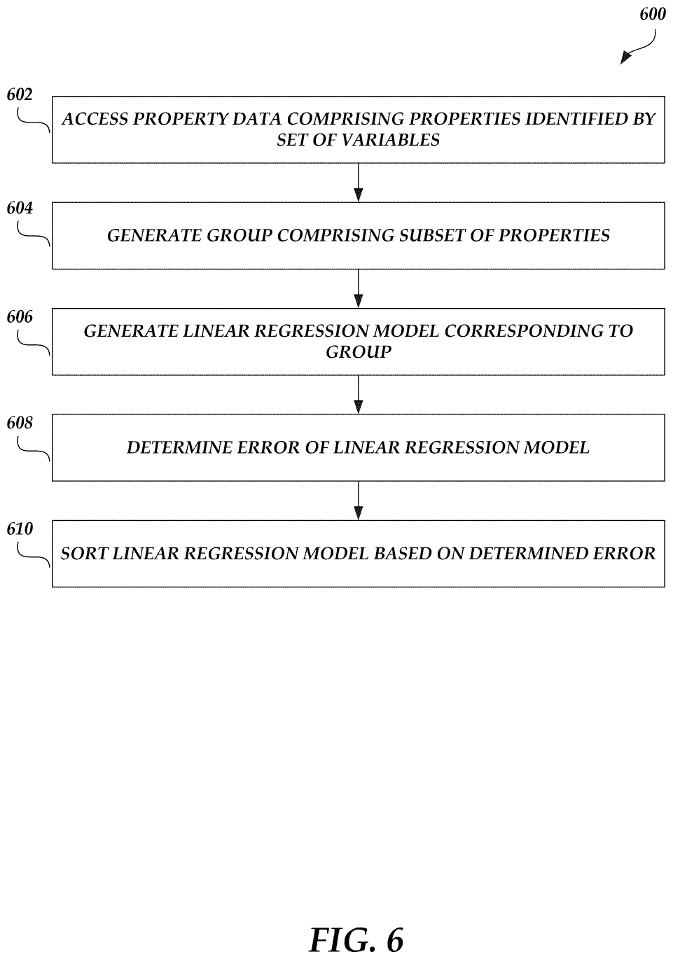

FIG. 6 is flow diagram showing an example routine 600 for generating a linear regression model corresponding to energy consumption estimation of properties, according to various aspects of the present disclosure. Routine 600 may be executed by the energy consumption estimation system 104 and various components of the energy consumption estimation system 104. Specifically, the routine 600 may be executed by a processor, such as the processing unit 502, shown in FIG. 5.

At block 602, property data is accessed by the energy consumption estimation system 104. As described herein, the property data of property energy data store 114 may comprise a plurality of properties and associated energy information with each of the plurality of properties. Property energy data store 114 may store information relating to energy information of properties. As noted herein, property energy information may be derived from various surveys, polls, and other sources that capture energy data associated with existing properties. In some examples, the energy consumption estimation system 104 accesses the property energy data store 114, which may be located remotely and accessible via the network 124. In some embodiments, each property of the plurality of properties is identified with a set of variables including a region, a climate, a property type, and a construction year. These variables indicate additional information associated with each property, and may be utilized by the energy consumption estimation system 104 to improve the accuracy of energy estimation.

At block 604, a group comprising a subset of the plurality of properties is generated. As noted herein, properties stored in the property energy data store 114 can be associated with variables (e.g., region, climate, property type, year built, area). These variables indicate additional information associated with each property, and may be utilized by the energy consumption estimation system 104 to improve the accuracy of energy estimation. To integrate property information into generated linear regression models, the energy consumption estimation system 104 may first, via the grouping system 106, generate groups. Each group may comprise properties that are classified by the combination of variables in that group. For example, the grouping system 106 may generate a group comprising properties that are identified by the following variables: Pacific (region), marine (climate), apartment in building with 2-4 units (property type), built within 1990-1999 (year built). The grouping system 106 may access, from the property energy data store 114, all properties that fit this description for classification as a group. In some embodiments, the grouping system 106 may determine a group for every combination of variables. Each property in the property energy data store 114 may be categorized into at least one group. Groups may be stored in the group data store 118.

At block 606, a linear regression model corresponding to the group is generated. In some embodiments, the linear regression model represents a correlation between estimated energy consumption and the area of each of the subset of the plurality of properties. The linear regression system 108 may access model data store 120. To generate a linear regression model for a group, the linear regression system 108 may input the group into the model of model data store 120 and any corresponding prompt or instruction to generate the linear regression model. In the example above, the linear regression system 108 may receive a property group corresponding to all properties from the property energy data store 114 that fit the description of: Pacific (region), marine (climate), apartment in building with 2-4 units (property type), built within 1990-1999 (year built). The linear regression system 108 may input this information into the model configured to output a linear regression model that describes total energy consumption v. area. In some embodiments, the linear regression system 108 may generate linear regression models for each property group for storage in the linear regression data store 122. As such, the linear regression system 108 may generate a linear regression model for each combination of variables such that each property of the property energy data store 114 is described by at least one linear regression model.

At block 608, error corresponding to the generated linear regression model is determined. The linear regression system 108 determines an error of each linear regression model. In some embodiments, the linear regression system 108 determines the error of the linear regression models using various error calculation methods or processes. In one instance, the linear regression system 108 calculates the mean absolute percentage error (“MAPE”) of each linear regression model. The MAPE calculated for each linear regression model may indicate the average magnitude of error produced by the generated linear regression.

At block 610, the linear regression model is sorted into a data store. In some embodiments, the linear model is sorted based on the determined error. the energy consumption estimation system 104 may sort each linear regression model into either first linear regression data store 122A or second linear regression data store 122B. In some embodiments, the energy consumption estimation system 104 may sort the linear regression models into additional data stores. Additionally, at block 610, the energy consumption estimation system 104 may sort each linear regression model based on the determined MAPE. In some embodiments, the energy consumption estimation system 104 may utilize a threshold percentage or value to determine which data store to store each linear regression model. For example, the energy consumption estimation system 104 may sort all linear regression models with a MAPE less than 35% into first linear regression data store 122A. In addition, the energy consumption estimation system 104 may sort all remaining linear regression models with a MAPE less than 45% into the second linear regression data store 122B. All linear regression models that do not meet these error threshold may be discarded. The energy consumption estimation system 104 may utilize various threshold percentages for sorting the linear regression models, and may include more or less data stores.

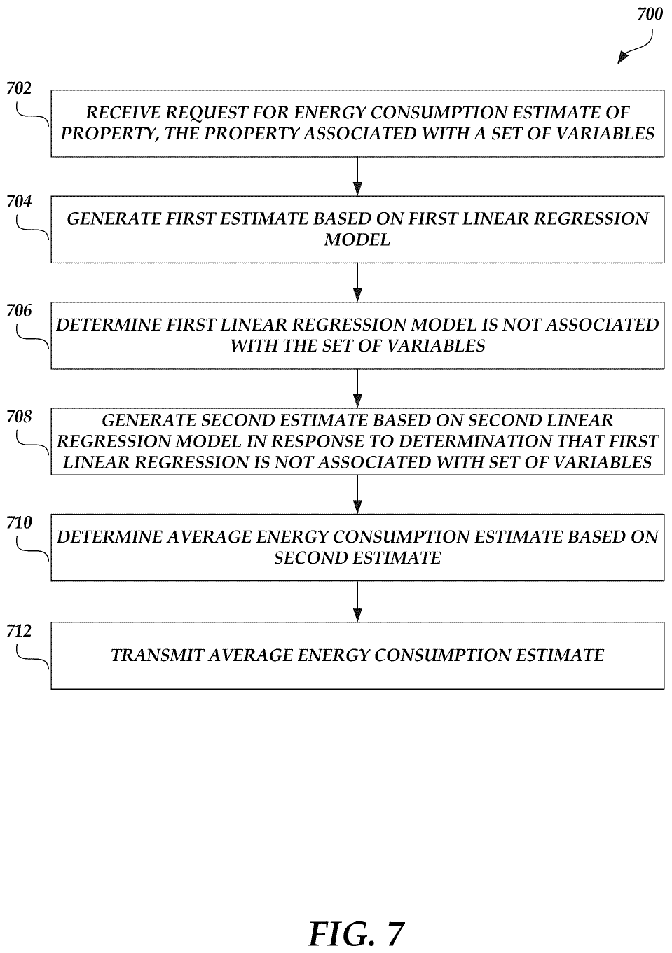

FIG. 7 is a flow diagram showing an example routine 700 for providing energy consumption estimations for properties based on generated linear regression models. Routine 700 may be executed by the energy consumption estimation system 104 and various components of the energy consumption estimation system 104. Specifically, the routine 700 may be executed by a processor, such as the processing unit 502, shown in FIG. 5.

At block 702, a request 302 for an energy consumption estimate of a property is received. In some embodiments, the requested property is associated with a set of variables. Request 302 may be a request for an energy consumption estimation of a property. The request 302 may indicate a request for an average energy consumption estimation of a property over a specified time period, such as a year (e.g., total gross annual energy consumption). In some embodiments, a user of the user device 102 may input a request 302 to the energy consumption estimation system 104 via the frontend 116. The request 302 may identify a specific property that is tied to a geographical location (e.g., identified by an address). In some cases, the request 302 may identify a hypothetical property that is not specifically tied to a real world geographical location, but may be identified in the request 302 by features or other identifiers. In some examples, the request 302 identifies the area (e.g., square footage) of the requested property.

At block 704, a first estimate based on a first linear regression model is generated. As described above with respect to FIG. 2, the first linear regression data store 122A may store a subset of generated linear regression models, such as those with a MAPE of less than 35%. To estimate the energy consumption of the requested property, the estimation system 110 may utilize the linear regression models in the first linear regression data store 122A to output an estimation 304. In some embodiments, the estimation system 110 may utilize each linear regression model of the first linear regression data store 122A to generate multiple estimations for a requested property.

At block 706, the first linear regression model is determined to not be associated with the set of variables of the requested property. Each linear regression model generated by the linear regression system 108 may be based on a group that defines a certain classification of properties (of property energy data store 114). Although property energy data store 114 may contain multiple properties that span various regions, climates, property types, etc., the available property data may not be wholly comprehensive. As such, there may be certain scenarios in which a requested property is not explicitly covered by the generated linear regression models. For example, request 302 may identify a multi-family house in a remote area of Alaska. Property energy data store 114 may not contain property information with these variables, and as such, the linear regression system 108 would not have taken this type of property into account when generating a linear regression model. In another instance, linear regression system 108 may have generated a linear regression model integrating a similar property (e.g., very cold climate, multi-family home), but may have discarded the linear regression model due to a high presence of error. As such, at block 706, the estimation system 110 may determine whether the requested property in the request 302 is covered by any one of the linear regression models stored in 122A.

At block 708, a second estimate based on a second linear regression model is generated. As noted herein, in the case when the estimation system 110 determines that the requested property is not covered by at least one of the linear regression models of the first linear regression data store 122A, the estimation system 110, at block 708, generates an estimation 304 corresponding to the requested property using a second linear regression model. As described above with respect to FIG. 2, the second linear regression data store 122B may store a subset of generated linear regression models, such as those with a MAPE of less than 45%. To estimate the energy consumption of the requested property, the estimation system 110 may utilize the linear regression models in the second linear regression data store 122B to output an estimation 304. In some embodiments, the estimation system 110 may utilize each linear regression model of the second linear regression data store 122B to generate multiple estimations for a requested property. In some embodiments, at 708, the estimation system 110 discards the estimations generated with the first linear regression data store 122A.

At block 710, an average energy consumption estimate based on the second estimate is determined. In some embodiments, at block 710, the average energy consumption estimate based on the second estimate is determined in response to the determination that the first linear regression model is not associated with the set of variables. Averaging system 112 may average the estimations from the second linear regression data store 122B into a single estimation 304.

At block 712, the average energy consumption estimate is transmitted. The average energy consumption estimate may be transmitted to a computing device, remote device, etc. The average energy consumption estimate may be output to a user of the user device 102, such as via the frontend 116. In some embodiments, it may be transmitted to another process, system, or device for further processing.

It is to be understood that not necessarily all objects or advantages may be achieved in accordance with any particular embodiment described herein. Thus, for example, those skilled in the art will recognize that certain embodiments may be configured to operate in a manner that achieves or optimizes one advantage or group of advantages as taught herein without necessarily achieving other objects or advantages as may be taught or suggested herein.

All of the processes described herein may be embodied in, and fully automated via, software code modules, including one or more specific computer-executable instructions, that are executed by a computing system. The computing system may include one or more computers or processors. The code modules may be stored in any type of non-transitory computer-readable medium or other computer storage device. Some or all the methods may be embodied in specialized computer hardware.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

The various illustrative logical blocks and modules described in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of electronic devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. A computing environment can include any type of computer system, including, but not limited to, a computer system based on a microprocessor, a mainframe computer, a digital signal processor, a portable electronic device, a device controller, or a computational engine within an appliance, to name a few.

Conditional language such as, among others, “can,” “could,” “might,” or “may,” unless specifically stated otherwise, are otherwise understood within the context as used in general to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Any process descriptions, elements or blocks in the flow diagrams described herein and/or depicted in the attached FIGs. should be understood as potentially representing modules, segments, or portions of code which include one or more executable instructions for implementing specific logical functions or elements in the process. Alternate implementations are included within the scope of the embodiments described herein in which elements or functions may be deleted, executed out of order from that shown, or discussed, including substantially concurrently or in reverse order, depending on the functionality involved as would be understood by those skilled in the art.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B, and C” can include a first processor configured to carry out recitation A working in conjunction with a second processor configured to carry out recitations B and C.

What is claimed is:

1. A system, comprising:
a computer-readable storage medium storing program instructions; and
one or more processors configured to execute the program instructions to cause the system to:
access property data, the property data comprising a plurality of properties and associated energy information with each of the plurality of properties, wherein each property of the plurality of properties is identified with a set of variables including a region, a climate, a property type, and a construction year;
generate a group comprising a subset of the plurality of properties identified by the set of variables;
generate a linear regression model corresponding to the group, the linear regression model representing a correlation between estimated energy consumption and an area of each of the subset of the plurality of properties;
determine an error corresponding to the generated linear regression model; and
sort the linear regression model into a first data store when the error is under a first error threshold and into a second data store when the error is under a second error threshold.

2. The system of claim 1, wherein the energy information comprises at least one of a statistic, survey, poll, investigation, energy usage, or a sampling.

3. The system of claim 1, wherein the error is a mean absolute percentage error.

4. The system of claim 1, wherein the one or more processors further cause the system to:
discard the linear regression model when the error is greater than the first error threshold and the second error threshold.

5. The system of claim 1, wherein the one or more processors are configured to execute the program instructions to further cause the system to:
generate a plurality of linear regression models corresponding to the group;
determine, for each linear regression model of the plurality of linear regression models, an error corresponding to the generated linear regression model; and
sort each linear regression model of the plurality of linear regression models into the first data store when the error is under a first error threshold and into the second data store when the error is under a second error threshold.

6. The system of claim 1, wherein the one or more processors are configured to execute the program instructions to further cause the system to:
generate an estimate of a property of the plurality of properties based on the linear regression model.

7. The system of claim 1, wherein the one or more processors are configured to execute the program instructions to further cause the system to:
generate a plurality of estimates of a property of the plurality of properties based on the linear regression model;
determine an average energy consumption estimate based on the plurality of estimates of the property; and
transmit the average energy consumption estimate to a computing device.

8. A system, comprising:
a computer-readable storage medium storing program instructions; and
one or more processors configured to execute the program instructions to cause the system to:
receive a request for an energy consumption estimate of a property, the property associated with a set of variables;
generate a first estimate of the property based on a first linear regression model;
determine that the first linear regression model is not associated with the set of variables;
generate a second estimate of the property based on a second linear regression model in response to the determination that the first linear regression model is not associated with the set of variables;
determine an average energy consumption estimate based on the second estimate of the property; and
transmit the average energy consumption estimate to a computing device.

9. The system of claim 8, wherein the set of variables includes at least one of a region, a climate, a property type, or a construction year.

10. The system of claim 8, wherein the first linear regression model has an error under a first error threshold.

11. The system of claim 10, wherein the second linear regression model has an error under a second error threshold, and wherein the second error threshold is greater than the first error threshold.

12. The system of claim 8, wherein the first linear regression model was generated based on a second set of variables different from the set of variables.

13. The system of claim 8, wherein the property is identified in the request by a geographical location.

14. A method, comprising:
accessing property data, the property data comprising a plurality of properties and associated energy information with each of the plurality of properties, wherein each property of the plurality of properties is identified with a set of variables including a region, a climate, a property type, and a construction year;
generating a group comprising a subset of the plurality of properties identified by the set of variables;
generating a linear regression model corresponding to the group, the linear regression model representing a correlation between estimated energy consumption and an area of each of the subset of the plurality of properties;
determining an error corresponding to the generated linear regression model; and
sorting the linear regression model into a first data store when the error is under a first error threshold and into a second data store when the error is under a second error threshold.

15. The method of claim 14, wherein the energy information comprises at least one of a statistic, survey, poll, investigation, energy usage, or a sampling.

16. The method of claim 14, wherein the error is a mean absolute percentage error.

17. The method of claim 14, further comprising:
discarding the linear regression model when the error is greater than the first error threshold and the second error threshold.

18. The method of claim 14, further comprising:
generating a plurality of linear regression models corresponding to the group;
determining, for each linear regression model of the plurality of linear regression models, an error corresponding to the generated linear regression model; and
sorting each linear regression model of the plurality of linear regression models into the first data store when the error is under a first error threshold and into the second data store when the error is under a second error threshold.

19. The method of claim 14, further comprising:
generating an estimate of a property of the plurality of properties based on the linear regression model.

20. The method of claim 14, further comprising:
generating a plurality of estimates of a property of the plurality of properties based on the linear regression model;
determining an average energy consumption estimate based on the plurality of estimates of the property; and
transmitting the average energy consumption estimate to a computing device.
